(19) United States
(12) Patent Application Publication
(10) Pub. No.: US 2004/0186793 A1
(43) Pub. Date: Sep. 23, 2004

(54) System and method for designing customer specified machining tips

(76) Inventors: Brice Harmand, La Jolla, CA (US); Steven M. Risch, Escondido, CA (US); Rafael Chevalier, La Roche Sur Foron (FR)

Correspondence Address: Eleanor M. Musick, Procopio Cory Hargreaves & Savitch LLP, Suite 2100, 530 B Street, San Diego, CA, 92101-4469, US

(21) Appl. No.: 10/814,685

(22) Filed: Mar. 30, 2004

Related U.S. Application Data
(62) Division of application No. 09/637,391, filed on Aug. 11, 2000, now abandoned.
(60) Provisional application No. 60/148,531, filed on Aug. 12, 1999.

(51) Int. Cl. G06F 17/60; G11C 8/00

(52) U.S. Cl. 705/27

(57) ABSTRACT

A method for designing a custom bit for use in machining valve seats of a cylinder engine head includes providing a design program to the customer for use with a personal computer. A bit manufacturer may either supply a hard copy of the design program to a customer or allow the customer access to the program electronically through, for example, an Internet web site. The design program provides the customer with a convenient and cost effective method for designing and submitting a custom cutting bit profile that may be used by the bit manufacturer to manufacture the custom cutting bit. The method for designing a custom bit of the present invention eliminates and/or reduces the timely and costly steps of manufacture associated with the current methods of custom bit design.

This application claims priority under 35 U.S.C. 119(e) to provisional U.S. patent application No. 60/148,531 filed Aug. 12, 1999.

### FIELD OF INVENTION

The present invention relates to a system and method for designing machining tips for machining valve seats of an engine cylinder head, and more specifically to a method and system for enabling a customer to generate a customer specified design of a machining tip utilizing a software package for use with the customer's personal computer, or utilizing an “on-line” application available at a manufacturer's Internet site.

### BACKGROUND

Cylinders of internal combustion engines having perfectly matched valve heads and valve seats produce an optimal seal. Cylinders that are sealed airtight when the valves are closed ensure efficient fuel consumption and transfer of power. Thus, the machining of valve seats of engine cylinder heads is necessary when the contact surfaces of the engine valves and valve seats become worn or damaged.

Valve seats are machined utilizing machining apparatus such as described in U.S. Pat. Nos. 5,613,809, 5,725,335, and 5,829,928 of Harmand, et al., each of which are incorporated herein by reference. The machining apparatus includes a cutting bit disposed at the end of a spindle to machine the valve seats of an engine cylinder head. The cutting bits are interchangeable and are chosen based upon various criteria including the make of a particular cylinder head. Cylinder head manufacturers commonly have specifications that describe the required profile of the valve seat. Thus, there are a variety of available standard cutting tips, also known as bits or cutting tools, that are designed to meet the specifications of a particular engine.

When a customer places an order for a stock tip or tips, the process of supplying the customer with the product is simply a matter of pulling the stock and delivering the request to the customer. The process of filling a customer's order is not always as simple as pulling stock, however. The request for custom, i.e., non-standard, profile tips is becoming more prevalent as the number of custom engine designs continue to increase. In addition, the number of orders for custom tips continues to increase as more and more customers experiment with different profiles in order to enhance engine performances. Custom tips are machined from tip blanks to match the customer's specifications. Tip blanks are commonly available in a variety of sizes to fit various machining apparatuses. Although tips may be made of any suitable material, a preferred bit is manufactured utilizing carbide. A typical manufactured and marketed tip is referred to as a “three angle carbide tips.” However, the phrase “three angle carbide tip” has a broader meaning than its literal language since there may be many more angles than three in a given tip.

The current process for ordering a custom tip is time consuming and costly. The process begins when the customer sketches a rough profile of the desired tip on a piece of paper, and delivers the sketch to the tip manufacturer by mail, facsimile, e-mail, etc. Alternatively, the customer may verbally describe the required tip profile to a tip manufacturer representative over the telephone, particularly in cases where an “as soon as possible” delivery of the machining tip is necessary. If the tip manufacturer needs additional information, the customer is re-contacted. The tip manufacturer then attempts to match the customer-specified tip dimensions to a blank tip. At this point in the process, it is possible that the customer's specifications will not fit any of the stock blank tips. In these circumstances, the tip is completely custom manufactured, and as a result, manufacturing costs increase and the customers may need to be re-contacted for authorizations to proceed.

Once an appropriate blank tip is identified, the manufacturer produces a profile drawing using a mechanical drawing software package. This step requires adding manufacturing tolerances dependent upon the specific machine utilized to manufacture the custom tip. Next, the profile drawing is presented to the customer for approval since there is potential for errors in the relaying of profile specifications from the customer to the manufacturer. Once final approval from the customer has been received, the software control program for the actual manufacturing of the tip on a bit cutting machine is prepared. The programming includes parameters for setting up the machine used to cut the bit. Once the bit is cut from the blank, the manufacturer inspects the tip, and verifies the final product against the customer's specification. Finally, the tip or tips are packed and shipped to the customer.

Although this method of doing business for providing a custom-designed tip is effective, it is time consuming with a low profit margin, particularly when the customer orders a single tip, which is often the case. The personnel-hours required to manufacture a single tip is not cost effective. However, the need for establishing a customer base, continuing existing customer-manufacturer relationships, and maintaining the manufacturer's business reputation mandate that each order be given full attention. Because custom design requires a great deal of manufacturer “hands-on” in each step of the design process, the cost for custom design increases and must be absorbed by either the customer or the manufacturer, particularly for individual tip orders.

Another disadvantage of the current custom design and manufacture process exists from the customer's point of view. Specifically, the customer must wait for the manufacturer to draw the tip profile, allocate additional time for reviewing and/or correcting the profile, and then wait for the actual manufacture of the tip. Also, customers have a need for an exact tool, or a means to set the tooling, that provides a quick and accurate set up of their machines for machining valve seats of engine cylinder heads.

Thus, it is desirable to shorten the process of custom tip design and manufacture. A more efficient method of providing custom cutting tips will reduce the manufacturing costs and the time required to deliver a final product. A streamlined process will allow a manufacturer the option to pass savings on to the customers to improve general business reputation of competitive prices and business efficiency.

### SUMMARY OF THE INVENTION

It is an advantage of the present invention to provide a system and method for reducing the time and cost to design and manufacture a custom cutting bit.

It is also an advantage to provide a custom bit design program that may be utilized on the customer's personal computer to guide the customer through a custom design of a cutting bit.

Another advantage to provide a method of custom bit design that utilizes Internet access to a custom bit design program that allows a customer to design a custom bit and return a finished design to a manufacturer's Internet site.

It is yet another advantage of the present invention is to provide a tool setting calculator for providing quick and accurate placement of tip holders on the tool holder of a machine for machining valve seats.

Still another advantage of the present invention is to provide a method of doing business for an efficient and cost effective way to receive design orders for machining cutting bits for use with an engine cylinder head machining apparatus.

An additional advantage of the present invention is to provide a software tool that raises the level of professionalism of the customer by allowing the customer to offer a prompt, on-the-spot quality service to his or her own customers who may be interested in a custom valve job.

In an exemplary embodiment of the present invention, the customer is provided with a specialized cutting bit design software program for use with a personal computer (“PC”). The cutting bit design program is compatible with a variety of operating systems and allows the customer to create a specification drawing, i.e. a blueprint, of a cutting bit by retrieving an existing bit profile, modifying an existing bit profile, or creating a new bit profile using a mouse, touch pad, or other user interface. The program may be provided to the customer by conventional storage media, e.g., diskette, CD ROM, or through any electronic transfer medium. The program can also be downloaded from an Internet site, or may be accessed through interactive use at a tip manufacturer's web site. Once the customer has designed his or her desired cutting bit, the design may be saved on a hard drive of the computer or on a removable memory including a diskette, ZIP, and CD/ROM. The profile may be printed as displayed on the computer screen as a hard copy and sent to the bit manufacturer for placing an order. The customer also has choices of electronically transferring the final cutting bit design by, e.g., electronic-mail (“e-mail”). Alternatively, if the customer is designing “on-line” at the bit manufacturer's site, the program will save the profile at the site memory, and the order may be placed automatically in accordance with site screen options.

The program of an exemplary embodiment generates codes that are utilized by the manufacturer to print a blueprint of the drawing. The customer's drawing is imported into a CAD program that generates blueprints that include the customer's name, address, etc., in a cartouche area similar to blueprints known in the art. In other embodiments of the present invention, the design program has an option for printing a blueprint of the bit design.

The program design procedure of the exemplary method and system of the present invention provides a step-by-step procedure to create a custom bit design. The program is designed to be “user friendly” by utilizing “pop-up” menus, tool bars, and prompts that take the customer through the design process. The availability of this design program encourages a customer to utilize the program, and thereby effectuates a time and cost efficient method of doing business that is beneficial to both the manufacturer and the customer.

The design program of the exemplary embodiment includes options to rapidly create a profile and simulate its application to determine whether it will work. The user may then determine whether to edit the profile without having to wait for a sample profile for a trial machining. Thus, the user saves time and money utilizing the design program. The program also allows the user to see multiple versions of one profile side by side for comparison. Thus, the software offers the user the ability to create the ideal profile for a particular cylinder head, taking into account such information as the dimension between the start of the profile and the actual beginning of the seat segment, the dimension between the end of the valve seat segment and the end of the profile, the relief angle or rake angle of the carbide tip, the valve seat identification, the valve seat “OD”, and the contact surface between the valve and the valve seat (seat width and margin). The program also provides an option for the user to specify special surface treatments required on the carbide tip. The design program of the exemplary embodiment further provides a customer with a means for saving additional pertinent information about any given cylinder head type for which he may wish to use a particular tip profile.

In the exemplary embodiment of the present invention, the customer uses a cutting bit design program to either create a new drawing of a tip profile or modify a drawing of an existing profile. Existing tip profiles may be stored, sorted and retrieved by carbide tip reference, engine type, and the valve seat angle and range of valve seat width, e.g. 450 at 1-1.20 mm. The user may store other information under the engine database type including the tip holder size/reference, the tool holder size/reference, the carbide pilot size, the valve overhang/protrusion or set-back, and any other information deemed useful to the machine operator that will use the tip design to manufacturer a carbide tip.

To begin the design process, the customer chooses an option for creating a new profile. The customer chooses a carbide blank to immediately determine which blank size is more appropriate for the customer's specific application. In one embodiment, the program automatically provides a window with a default tip blank that may be changed by choosing an alternate blank tip. The blank tip outline indicates the areas in which the profile may be expanded and the areas that are not feasible for a tip profile. In the exemplary embodiment, the customer also has the option to create a new profile by modifying a profile that is retrieved from a database. In alternate embodiments, profile databases are included in the design program depending upon the version purchased or delivered to the customer. In an interactive environment, access to databases may be controllable by utilizing access numbers and similar authorization schemes. The database of the exemplary embodiment provides already-designed profiles. Generally, modification of a preexisting database profile shortens the customer's design time.

In the exemplary embodiment, the software automatically takes into account the size of the actual valve that will be installed in the cylinder head after the valve seat has been machined. The software gives a dimension for adjusting the tip holder based on the profile of the carbide tip and the size of the valve. The compatibility between the cylinder head, valve and carbide tip profile, are controlled by the software in terms of valve seat depth and required valve adjustment. The design program of the exemplary embodiment calculates the exact positioning of the tip holder on the tool holder according to the specified diameter of the valve and margin. The program outputs dimensions for adjusting the tip holder easily and with great accuracy using a pair of calipers, thereby eliminating the need for tool setting fixtures.

After the user selects a profile, the user is ready to construct a new bit design. The profile may be drawn starting from either the inside edge of the valve seat or from the outside edge of the valve seat. In the exemplary embodiment, the profile is created by specifying a first segment followed by subsequent segments starting from the inside edge of the valve seat. The program prompts the user, either by specific instruction or by means of a window, for information regarding a first segment. A “segment” is either a line or an arc, and the profile is completed by adding one segment after another. Line segments are definable in a variety of ways including by an angle and length, by an angle and horizontal projection, or by an angle and an intersection with respect to an edge of the blank selected. A radius segment is definable by a beginning angle, by an ending angle and a radius/length, by an intersection with respect to a blank edge, by a length and a beginning/ending angle, or by a chord having length and concavity for design modifications-whenever the user wishes to transform a line into an arc. The exemplary embodiment also allows a user to cut and paste different portions of an existing profile or profiles for use in his or her new design. The design program is international, allowing the entered values to be expressed in either metric, i.e., millimeters, or U.S. Standard Customary, i.e. inches. Similarly, the angles may be expressed in degrees, radians, grades or percentages.

As the customer creates a profile, each segment of the profile appears on the screen as new defining values are entered. In an exemplary embodiment, the positioning of the new profile comprising the series of segments onto the tip blank is automatic. In this embodiment, the design program attempts to coincide the beginning and ending points of the profile with the lower lateral edges of the selected blank. The program provides an error notice or other signal when the profile cannot be created from a particular blank, or when the profile extends into the area required to firmly secure the tip in the tip holder. In either case, the program user may select a different tip blank or modify the profile. In another embodiment, user-directed positioning of the new profile is available as an option. The customer utilizes a mouse or any other pointing device to roughly position the profile over the selected blank. The design program also provides options for automatically moving the profile along the X and/or Y axes of the chosen blank in small increments. In the exemplary embodiment, the increment value is 1/100 mm or 1/1000 mm to allow for design precision.

A completed profile segment may be superimposed or positioned upon any available blank simply by selecting another blank tip to determine immediately whether a desired bit design fits a blank, or whether other blanks are usable for the design. There may be a variety of blank tips having varying dimensions that are compatible with different models of machining apparatuses. Tip blanks are selectable by the customer within a manufacturers' classification. If the desired design does not fit within a chosen blank, the customer may choose a different machining apparatus compatible blank. Designs that do not fit any pre-existing manufacturer's blanks, must be completely custom manufactured.

The design program of the exemplary embodiment provides multi-tasking utilizing program windows. Each tip profile is designed within an adjustable window, and several tip profile windows may be viewed at one time. The program also allows for enlargement of the profile and/or window. Information relevant to the geometric characteristics of the tip within an active window are displayed within a separate window.

The exemplary embodiment of a method of doing business allows the program to be accessed by installation of the software from a disk or via an Internet site of the bit manufacturer. For those customers with Internet capabilities, access to the software design package is convenient and provides an efficient and time saving method to design and order bits. In the exemplary embodiment, the customer selects the manufacturer's web site to design and order cutting bits. When the design/order button is selected, a screen appears for additional choices of ordering stock bits or designing a custom bit. Upon selection ordering stock bits, the customer may choose a desired bit and order the bit through a shopping cart method as is known in the art. Typically, once the customer chooses a product, he or she must fill out a credit information form which requests information such as a credit card number, address for delivery, and phone number. The customer then verifies the order by selecting an “order product” button.

For custom design of the present invention, the customer can gain access to a custom design program by an access code or password. If the customer does not have an access code, he or she is assigned one by contacting the bit manufacturer directly or by filling out a registration screen. The registration screen requests credit information and other user profile information, and informs the customer of the prices and options available for design. In one embodiment, the customer may download the design software for a fee. In another embodiment, the customer requests access to an interactive program that steps the customer through the design process. Once the design is complete, the customer may save the design for future use. The customer may also choose to submit the design for an order. Fees for use of the design site and the cost of the bit are automatically billed to the customer's credit card. In another embodiment, access to the interactive design screen may also be available at no cost to the potential customer. In this embodiment, the fee for the use of the software is transparent and is absorbed in the cost of the custom manufactured cutting bit. In addition, the interactive design method allows the bit manufacturer to maintain control over its proprietary design programming and methods.

The use of a design program on an Internet site benefits the manufacturer in a variety of ways including a method of gathering customer profiles that can later be used for mailings, etc. In addition, an Internet site that includes this unique method of doing business reaches worldwide and generates name recognition for the manufacturer, particularly where the bit manufacturer is the is the only manufacturer to offer an accessible and convenient method of designing and ordering custom bits.

The design program of the exemplary embodiment provides an advantage for the user in his or her own business in that it raises the level of professionalism of the user by allowing prompt and on-the-spot service for his or her own customers. For example, an customer may bring a cylinder head into a machine shop requesting information on what can be done to upgrade, enhance, or repair the cylinder. In response, the machine shop owner, i.e., user, may utilize the design program to build a profile with the customer by his side, and explain to the customer the benefits of the custom profile. This process provides a first rate service to the customer, eliminates guessing, increases interaction and between the machine shop and the end customer, and enhances business reputation in the field.

### BRIEF DESCRIPTION OF THE DRAWINGS

Understanding of the present invention will be facilitated by consideration of the following detailed description of preferred embodiments of the present invention taken in conjunction with the accompanying drawings, in which like numerals refer to parts, and in which:

FIG. 1 is a flow chart for a cutting bit design program;

FIG. 2 is a flow chart for modification of an existing bit profile;

FIG. 3 illustrates typical blank profiles that are available to the customer in the design program;

FIG. 4 illustrates a cutting bit positioned on a tip holder;

FIG. 5 shows typical specifications of a form tip;

FIG. 6a illustrates a blueprint-type drawing for a custom bit;

FIG. 6b shows the custom bit of FIG. 6a generated utilizing the design program of a preferred embodiment;

FIG. 6c shows the custom bit of FIG. 6b superimposed on an alternate blank bit;

FIG. 6d illustrates the segment information of the custom bit of FIG. 6b;

FIG. 7a illustrates placement of a first segment of a first method of designing a custom bit;

FIG. 7b illustrates placement of a second segment;

FIG. 7c illustrates placement of a third segment;

FIG. 7d illustrates placement of a fourth segment;

FIG. 7e illustrates placement of a fifth segment;

FIG. 8a illustrates placement of a first segment in a method of a preferred embodiment of designing a custom bit utilizing a design program;

FIG. 8b illustrates placement of a second segment in a method of a preferred embodiment;

FIG. 8c illustrates placement of a third segment in a method of a preferred embodiment;

FIG. 8d illustrates placement of a fourth segment in a method of a preferred embodiment;

FIG. 8e illustrates placement of a fifth segment in a method of a preferred embodiment;

FIG. 9 shows the segment information for the bit design of FIGS. 8a-8e;

FIG. 10a illustrates a line segment creation window of a toolbox window of a preferred embodiment;

FIG. 10b illustrates a portion of an arc segment creation window of a toolbox window of a preferred embodiment;

FIG. 11 illustrates an elastics window of a toolbox window of a preferred embodiment;

FIG. 12 illustrates a blanks window of a toolbox window of a preferred embodiment;

FIG. 13 illustrates a typical window of a design program of a preferred embodiment;

FIG. 14 illustrates a tip holder adjustment window of a design program of a preferred embodiment;

FIG. 15a illustrates the addition of a passive segment of the bit design of FIG. 8e;

FIG. 15b illustrates the segment information of the bit design of FIG. 15a;

FIG. 16a shows an unmodified bit design;

FIG. 16b shows the bit design of FIG. 16a with an x-axis displacement of the profile;

FIG. 16c shows the bit design of FIG. 16a with an x-axis and y-axis modification of an elastic segment; and

FIG. 17 illustrates a manufacturer/customer method of designing custom bits of a preferred embodiment of the present invention.

### DETAILED DESCRIPTION OF THE PREFERRED EMBODIMENT

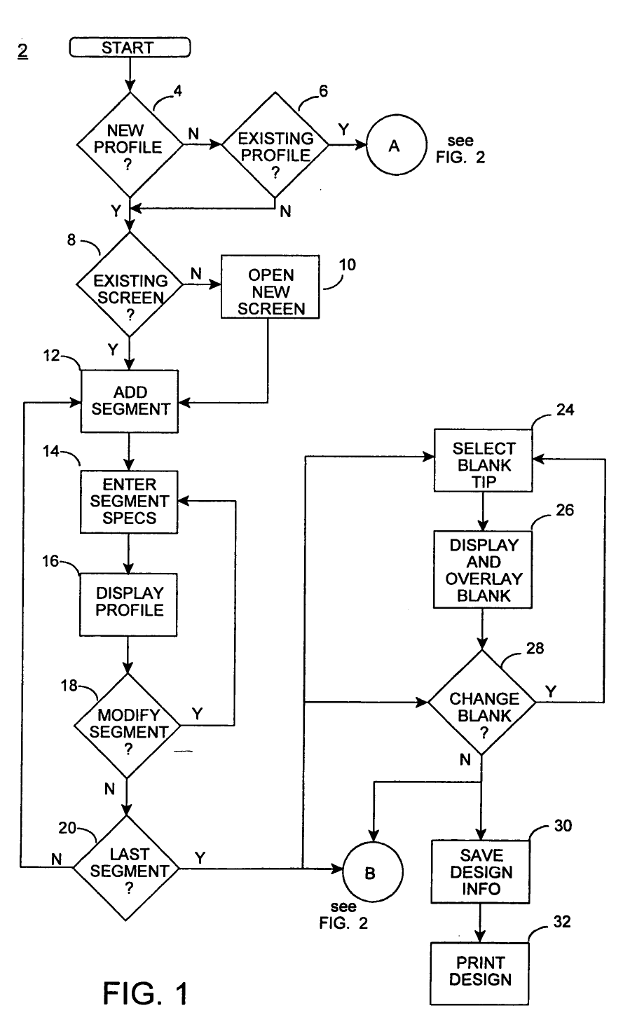

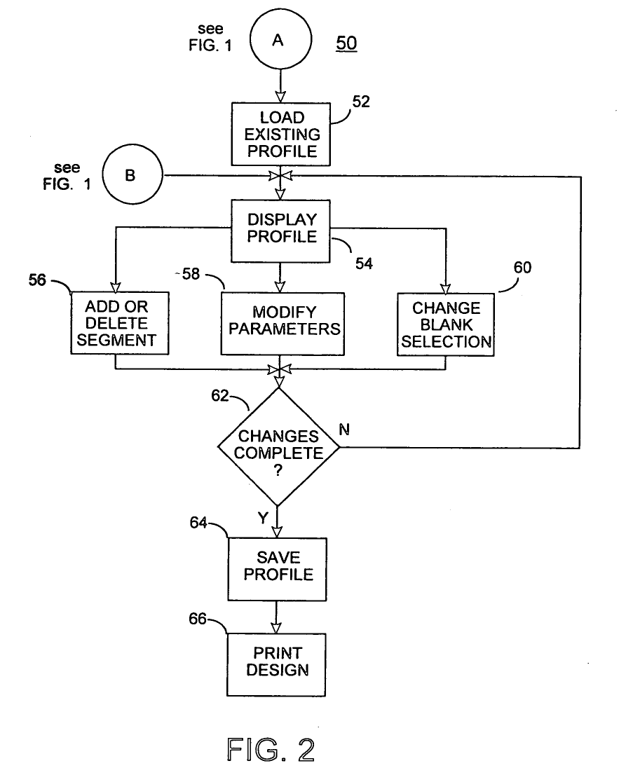

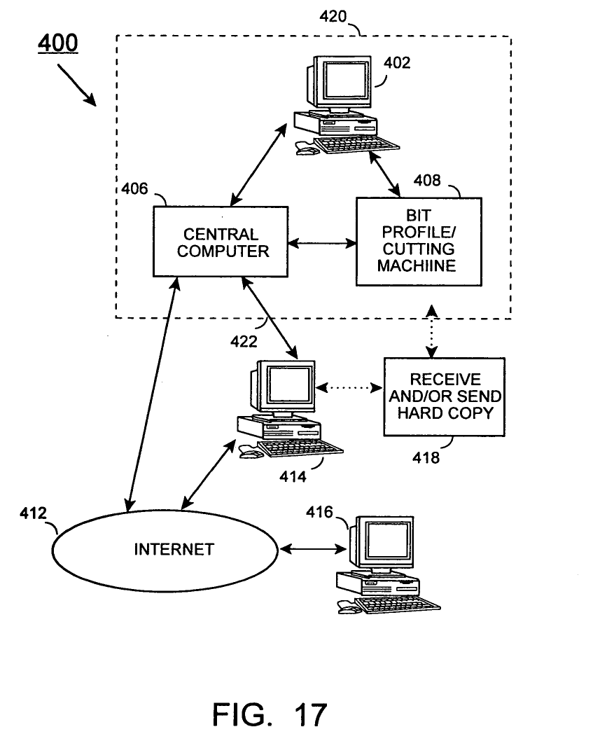

The flow chart of FIG. 1 shows a basic bit-design program 2 for designing custom bits in a preferred embodiment of the present invention. As shown in FIG. 17, the bit-design program 2 may be available interactively at a bit manufacturer's Internet site 422, or may be loaded directly onto a customer's personal computer 414 utilizing a hard copy 418 of the bit-design program 2. The bit-design program 2 presents the customer with a user-friendly interface having a variety of pop-up menus and tool bars. The preferred embodiment provides an option of design-by-prompt wherein the program guides the user through a design, step by step. This method of designing custom bits, wherein the customer prepares his or her-own design through use of a bit-design program 2 made available by the bit manufacturer 420, presents an improved business mode of operation. Specifically, the bit-design program 2 provides a time and cost efficient alternative to the present process of custom bit design.

The bit-design program 2 of the preferred embodiment may include an authorization code to access/execute the program 2. Authorization may be obtained in a number of ways including purchase of the bit-design program, a repeat customer authorized use of the program 2, e.g. over the Internet 412 as shown in FIG. 17, or by a guaranteed order of a custom bit wherein the cost of the bit-design program 2 is absorbed into the cost of the manufactured bit or bits.

Referring to FIG. 1, after the user starts or enters into the bit-design program 2, he or she has a choice to either create a new profile 4 or modify an existing profile 6. A “profile” describes the cutting edge of a cutting bit that is utilized to machine engine cylinder heads. An existing profile 6 includes the user's own designs as well as library designs. In one embodiment of the invention, the library designs are optional to purchase or use of the program. In an alternate embodiment, the library designs are included in the program. A new profile is created on an existing 8 or on a new screen/window 10, both of which may include a default blank tip. The user begins the bit design by adding segments 12. A typical profile utilizes three segments, however, the bit-design program 2 of a preferred embodiment has no constraint as to the number of segments that may be specified. A segment is either a line segment or a radius/arc segment. The user adds the segment 12 by entering the segment specifications 14. For example, a specification of 60 degrees at 4.5 millimeters instructs the bit-design program 2 to add a segment that is 60 degrees with respect to a chosen reference point, such as the bottom edge of the bit which corresponds to a first horizontal, wherein the segment has a length of 4.5 millimeters.

Immediately upon entering the segment specifications 14, the bit-design program 2 displays the profile 16 with all added segments. The profile of the preferred embodiment is displayed 16 as overlaid on a chosen or default blank that is included in the existing or new window 8, 10. In a preferred embodiment, the segment specifications 14 may be displayed in a separate program window. The user may modify the current segment 18 by re-entering segment specifications 14. The user is then prompted to add additional segments 20.

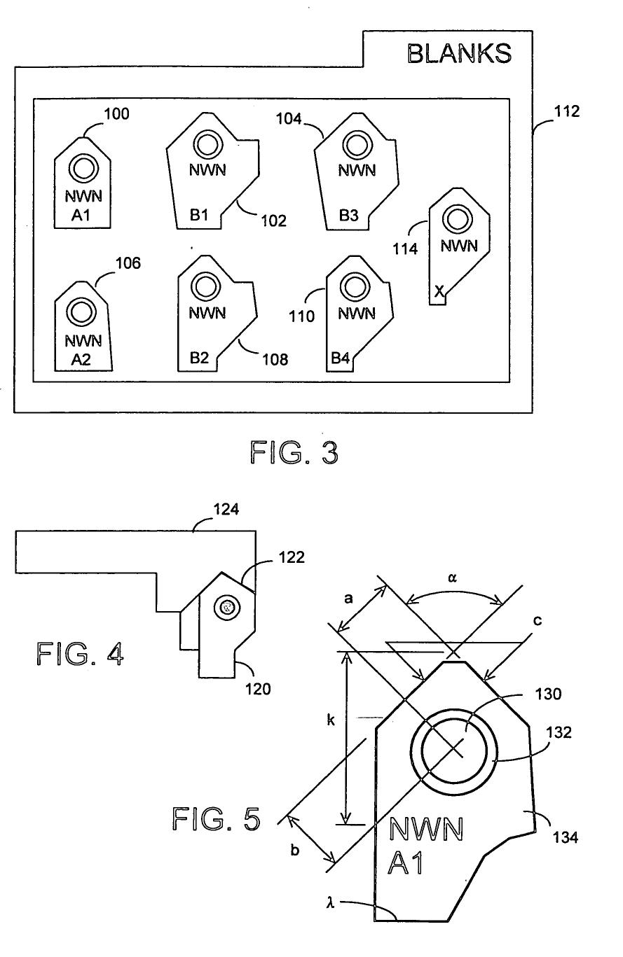

Once the last segment has been entered 20, the user may select a blank tip 24 from a manufacturer's library and overlay the blank tip 26 on the profile 16. In a preferred embodiment that displays a default blank tip, the user may choose to change the blank tip 28. Examples of blank tips 112 are illustrated in FIG. 3. Different tip manufacturers may have any number of blank tips 100-110, 114. Referring again to FIG. 1, the blank tip is displayed and overlaid onto the new profile 26 to determine whether the new profile fits the blank tip. If the profile does not match the blank tip, then another blank tip may be chosen 28. In a preferred embodiment, the blank size is not necessarily selected at the end of the design process. In fact, it may be suggested that the user start with the shortest and most compact blank available because it is likely to be the most rigid. As the profile is designed, the blank size may increase to fit the profile.

Once the design is complete, and the user verifies a blank tip choice, the design may be saved 30 on a memory device. The bit-design program 2 of a preferred embodiment further provides an option for printing 32 a hard copy of the bit design for use by the customer or a bit manufacturer. As illustrated in FIG. 17, the hard copy 418 of the design may be sent to the manufacturer. In other embodiments of the present invention, a bit design may be stored in the customer's computer 414, 416 and forwarded to the bit manufacturer through electronic means 412.

FIG. 2 is a continuation of the bit-design program 2 of FIG. 1, and shows the steps for modifying an existing profile. If the user chooses to modify an existing profile 6, as shown in FIG. 1, then the design program executes a modify profile module 50. The user is prompted to load an existing profile 52. Once the existing profile is chosen, it is displayed 54. The user then chooses to add or delete a segment 56, modify the parameters of an existing segment 58, or change a blank selection 60. After completion of the changes 62, the modified profile is saved 64 and printed 66 or electronically submitted for manufacture.

The flowcharts of FIGS. 1 and 2 represent a basic flow of one embodiment of the present invention that may utilize prompting to guide a customer in the creation of a bit profile. In a preferred embodiment, the user is provided with pop-up menus and tool bars, and he or she directs the flow of the design procedure. Other embodiments of the present invention may utilize a combination of prompted and non-prompted designing. Thus, the step-by-step process of designing a profile may vary for each user and for each design session.

As illustrated in FIG. 17, the bit-design software program and resulting profile design of the preferred embodiment is compatible with the software of the bit-cutting machine 408 utilized by the bit manufacturer 420. The design may be directly uploaded to the bit-cutting machine either through use of media such as diskettes 418, or through an electronic link such as a direct telephone link 422, the Internet 416 or e-mail from the customer's computer systems 414, 416 to the central computer 406 of the bit manufacturer 420. This capability allows the customer to re-use a custom bit design, and reduces the manufacturing time in loading the profile onto the bit-cutting machine 408. This capability is particularly cost and time efficient for orders of multiple bits or replacement bits.

FIG. 5 illustrates a manufactured tip 134 and the variety of possible specifications that the bit-design program 2 must recognize. Precision positioning of the tip seat angle and proper tightening of the tip result directly from parameters a, b, c, α. FIG. 4 illustrates a cutting bit 120 seated 122 in a tip holder 124. Both the positioning of the seat angle 122 of the tip 120 and proper tightening of the tip 120 are critical to ensure adequate rigidity and to eliminate chattering of the tip 120 in the tip holder 124. Referring back to FIG. 5, the seat angle 132 of the screw hole 130 must be manufactured to ensure maximum pressure on the tips in their housing. The cutting tip 134 may be manufactured from any material, however, a preferred material is specially treated carbide to ensure that the cutting edges of the tips are as strong as possible. The design of the custom bit utilizing the design program of the preferred embodiment automatically adds the specification of a relief angle λ of the base of the tip in order to avoid heeling. Standard relief angle λ are 8°, 10°, or 12°, with minimum and maximum relief angles of 0° and 32°, respectively. Principle factors in choosing relief angles are the material rigidity of the bit, and the valve chamber diameter. Other embodiments of the present invention allow the user to specify a relief angle.

As the program checks the overlaid blank against the customer's design, the tolerance dimension k is verified. It is important that this dimension is close to tolerance in order to make the tips completely interchangeable without adjustment of the tool holder. As shown in FIG. 14, the bit-design program of the preferred embodiment includes an option for calculating the exact positioning 294 of the tip holder 288 on the tool holder 286 according to the diameter of the valve 272, the pilot diameter 274, and the entered margin 280. The tip holder adjustment feature 270 eliminates the need for guess work by providing accurate tool set-up specifications. Thus, tool setting fixtures are not required, and the amount of time to machine a cylinder head is dramatically reduced. The tool setting calculator of FIG. 14 is an important feature, alone, for customers who buy only standard tips and do not want to, or need to, design custom tips yet need a means to set their tooling properly and accurately.

The specifications of a cutting bit as shown in FIG. 5 are used to manufacture a custom bit from a blank bit. FIG. 3 illustrates blank bits 100, 102, 104, 106, 108, 110 having various sizes. Blank bit 114 represents alternate blank bits that may be included in the manufacturer's inventory. The bits may be designated using a variety of designators that are often dependent upon the practices of a particular manufacturer. The bits range in size from the smallest bit 106 having few facets, to the largest bit 102 having many facets. The design program utilizes the blank bit overlays to determine an optimal bit 100-110 for the customer's design. The custom profile may fit on more than one blank bit size 100-110, in which circumstance the customer/manufacturer may choose an acceptable blank bit that is the closest fit for the profile, or according to criteria such as availability and cost.

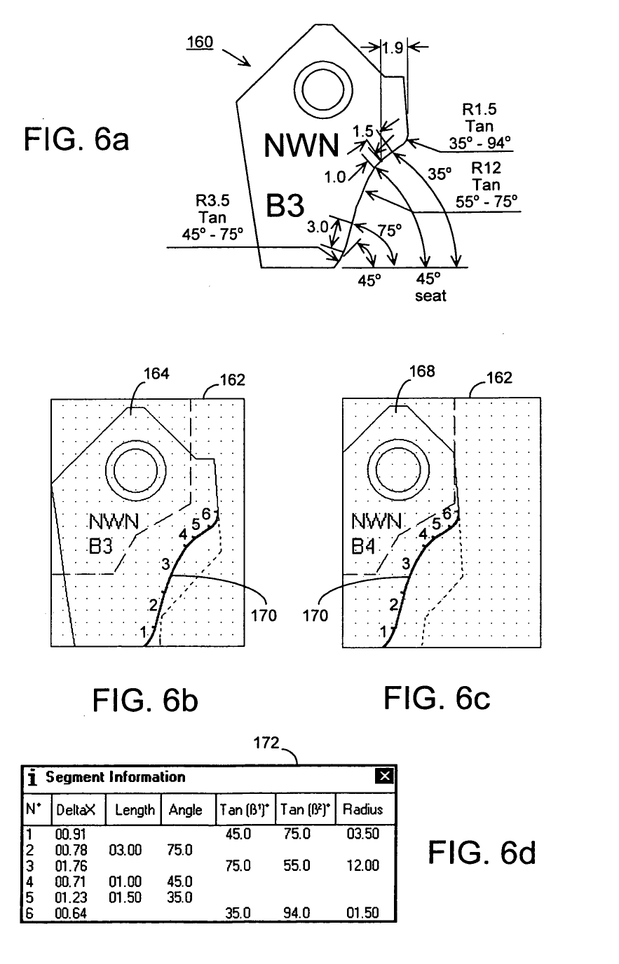

FIG. 6a shows a custom design 160 having complex specifications that include both line segments and radius segments. The bit may be manufactured from a B3 blank bit 104 as shown in FIG. 3. In the prior art methods of specifying a custom bit, the custom design 160 had to be drawn, as shown, on a blue print-type drawing of a blank bit. Any change, including a change in blank tip size, necessitated the time consuming process of re-drawing the custom design 160. FIGS. 6b, 6c, and 6d illustrate a design process of the custom bit of FIG. 6a utilizing a preferred embodiment of the present invention. The bit profile 170 is overlaid on a blank bit 164 in a screen 162, and consists of a series of line and arc segments. The segment information 172 is listed in a separate window as shown in FIG. 6d, and directly corresponds to the information of the hand-drawn bit profile of FIG. 6a. Numerous segment specifications, lines or radii, may be specified to create very complex profiles. As shown in FIG. 6c, the bit profile 170 may be overlaid on an alternate blank bit 168 without the need to re-specify the segment information 172.

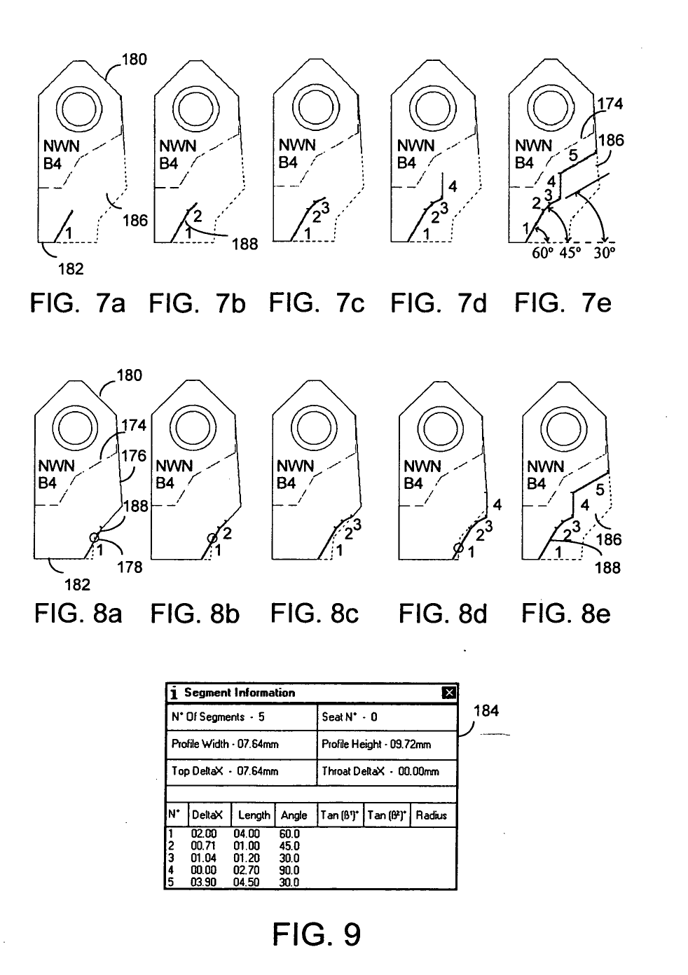

FIGS. 7a-7e and FIGS. 8a-8e illustrate two modes of designing a custom bit utilizing the present invention as generally illustrated in the flowcharts of FIGS. 1 and 2. FIGS. 7a-7e illustrate the display screens of a design process of a first embodiment. In the first step of a design process, the customer chooses a blank bit 180 from a manufacture's library of blank bits. The chosen bit is displayed to the customer. The blank bit chosen in this example is a B4 blank bit 110, as shown in FIG. 3. The user then adds segments, one by one, until the profile is complete. In FIG. 7a, the customer specifies a first line segment having a length of 4 units at an angle of 60 degrees with respect to the base 182. The updated profile is displayed and overlain on the tip blank 180. The customer continues the design by adding a second line segment as shown in FIG. 7b, a third line segment as shown in FIG. 7c, a fourth line segment as shown in FIG. 7d, and a fifth line segment as shown in FIG. 7e. After each addition or modification, the profile display is updated. The first embodiment design program adds segments from left to right, corresponding to a valve seat facet closest to the seat center to a facet furthest from the seat center. In alternate embodiments, the program allows the segments to be added from right to left. The first embodiment as described above requires the user to place the first segment at an arbitrary position along the base 182, and later adjust the profile position to fit within the allowable area 186 of the blank bit 180. The “allowable area” 186 is the area outside of the tool tip holder limit 174 which appears as a dashed line over each blank 180. This tool tip holder limit 174 is the inside limit of a profile 188, and any profile 188 that passes this limit 174 requires an undesirable modification of a tool tip holder 288, as shown in FIG. 14.

FIGS. 8a-8e illustrate the display screens of a design process of a preferred embodiment. The preferred embodiment automatically places each segment such that a first end of the profile 188 has a starting point on the base 182 of the blank bit 180 and a second end of the profile 188 has an ending point on the cutting edge 176 of the blank bit 180. Referring to FIG. 9, the segment information 184 lists all of the segments including the first segment which has a length of four units at an angle of 60 degrees. This segment is shown in FIG. 8a. The circle represents an error indicator 178 flagging the user that the profile extends beyond the allowable area 186. The second segment is appended to the first segment in FIG. 8b, and has a length of one unit at an angle of 45 degrees. The addition of the third segment, shown in FIG. 8c, brings the profile within the allowable area 186. The addition of the forth vertical segment of FIG. 8d, and the fifth segment of FIG. 8e, complete the profile 188. The automatic placing of the segments of the preferred embodiment eliminates the need for the user to attempt to line up the profile 188 between the lower lateral edges of the base 182 and the cutting edge 186, and results in a fast and accurate profile 188 placement.

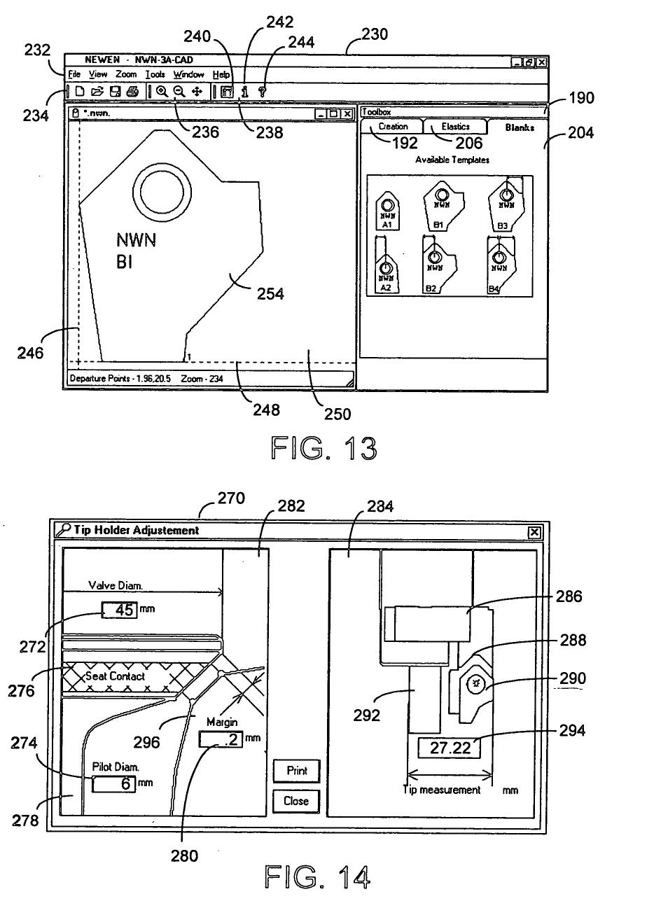

FIG. 13 illustrates a screen 230 of the bit-design program of a preferred embodiment. The screen 230 includes a pull-down menu 232, a standard tool bar 234, a zoom tool bar 236, and an information tool bar 238. The screen 230 also provides an area for a number of pop up windows including any desired number of work area windows 250 and a toolbox window 252. In a preferred embodiment, the work area window 250 appears upon start-up of the program, and shows a default blank bit 254 aligned with an x-axis 248 and a y-axis 246. A display of the developing profile occurs in the work area window 250. The toolbox window 252 provides the controls for creating a profile, modifying a profile, and choosing available blanks for an active work area window 250.

The tool bars 234, 236, 238 may be shown or hidden as required. The standard tool bar 234 includes an icon for creating a new window, opening an existing file, saving the profile to memory, and printing the profile. The zoom tool bar 236 includes icons for zooming in and out, and panning across the work area window 250. The zoom of the pull-down menu 232 may further include options for zooming to show an actual size of a 1:1 ratio of a tip, and zooming to fit the tip to the window size. The information tool bar 238 includes a tool setting calculator or tip holder adjustment 240 icon, a segment information 242 icon, and an index 244 icon. The index 244 icon may be chosen to access an index of all of the terms of the bit-design program.

The segment information 242 icon of the information tool bar 238 calls up a window that displays segment information 184, as shown in FIG. 9. The segment information box displays global values for the profile of the active work area 250 as well as displaying the values for each of the segments of the profile. Global values that are displayed include the number of segments, the segment number that is designated as the seat, the total width of the profile, the total height of the profile, the throat “deltax”, or the change along the x-axis from the outside of the seat segment to the beginning of the first segment, and the top “deltax”, or the change along the x-axis from the inside of the seat segment to the beginning of the first segment. The segment details list the values for each of the segments, wherein the values displayed depend upon the type of segment, i.e. line or arc.

The tool setting calculator 240 icon of a preferred embodiment may be selected to open a tip holder adjustment window 270 as shown in FIG. 14. The tool setting calculator 270 is utilized to calculate tool adjustments for a bit design. In a first portion 282 of the tip holder adjustment window 270, a valve having a seat contact 276 and a pilot 278 is shown seated in a valve seat 296. A second portion 284 of the window 270 shows a machining head with a machining tip 290 placed in a tip holder 288 of a tool holder 286. The user enters a valve diameter 272, a pilot diameter 274, and a margin value 280, and the bit-design program automatically calculates the tip measurement value 294. The tip measurement value 294 provides an accurate measurement for setting the tip holder 288 according to a distance from a centering pilot 292 to a farthest point on the machining tip 290 and/or tip holder 288. This feature eliminates the need for setting the tip holder 288 utilizing tool setting fixtures of the prior art. In a preferred embodiment, the tip measurement value 294 corresponds to the active tip design window 250, and as further described below, the tip profile must designate a seat segment.

The pull-down menu 232 of the preferred embodiment may further include options for changing the profile colors to suit personal needs. Various colors may be chosen to highlight the segments of the profile, the x-axis and y-axis, the work area window 250 grid, etc. The bit-design program provides a default color option for selecting a default color scheme. The pull-down menu 232 may also provide a windows selections for manipulating window placement. The windows for different profiles may be cascaded, tiled, or arranged horizontally or vertically. The file selection includes a list at the bottom of this menu that shows all open windows. By selecting one of the entries,the chosen window will become the topmost window on the screen. This feature is useful when several profiles are open at the same time. A help option of a preferred embodiment includes a search engine for searching for text within a help file. The company and registration information may also be accessed through the help file.

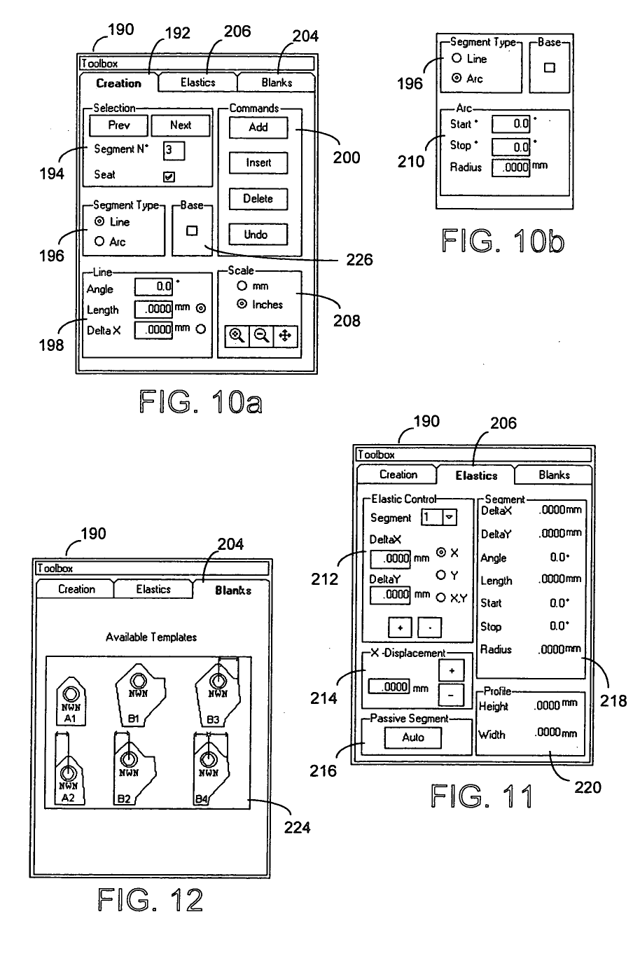

Continuing with FIG. 13, a toolbox 190 is utilized to create and modify a custom tip profile. The toolbox 190 is composed of three principal sections including the creation 260, elastics 258, and blanks 256 windows. The creation window of the preferred embodiment, as shown in FIG. 10a, provides action buttons to add, delete, modify and specify segments. The elastics window 206, as shown in FIG. 11, provides controls for modify segments dynamically. The blanks window, as shown in FIG. 12, contains a bank tip selection. The number of blanks shown in FIG. 12 is for illustrative purposes, only, and a manufacturer may have any number of stock blank tips available for use with the bit-design program.

Referring again to FIG. 10a, the creation window 192 includes a selection box 194 that includes “previous” and “next” buttons that may be used to select a given segment. A “segment n°” box displays the currently selected segment number. Alternatively, a segment number may be entered directly into the segment number box. A “seat” box allows for the selection of the segment that has been determined to be the valve seat segment. In a preferred embodiment of the present invention, each profile should include one segment designated as the seat segment. FIG. 10a illustrates a third segment as the selected valve seat segment.

A commands box 200 is also included in the creation window 192. The commands box 200 of a preferred embodiment includes an add, an insert, a delete, and an undo button. The “Add” button is utilized to add a new segment to the end of the current profile, while the “Insert” button inserts a new segment before the currently selected segment. Thus, the Add and Insert buttons differ by the introduction point of the new segment. The “Delete” button deletes the currently selected segment as shown in the selection box 194, and the “Undo” button undoes the last delete.

Continuing with the creation window 192 as shown in FIG. 10a, a segment type box 196 provides selection areas for specifying whether the current segment is an arc or a line. If the “Line” option is chosen, then the creation window 192 shows a line input box 198 that includes input areas for specifying the angle and the “deltax” or the length of a line segment. The input of only one of the deltax or the length is required, and the counterpart, i.e. the unspecified parameter, will automatically be calculated and displayed in the appropriate input area. The line input box 198 also includes option bullets adjacent the length and deltax values to allow an option for specifying that the selected value remain constant if the segment is modified. Should any new value be entered which would force the profile to exceed the tip limits, i.e. the allowable area, a message will be displayed and the previous values will be re-instated.

If the “Arc” option is chosen, then the creation window 192 displays an alternate arc input box 210, as shown in FIG. 10b, in place of the line input box 198. Creation of an arc segment requires specification of all three values, including Start, Stop, and Radius. The start value specifies the starting tangent angle of the arc, and the stop value specifies the ending tangent angle of the arc. Ideally, the arc tangents are equal to the angles of the preceding and the following segments. The input areas of the line input box 198 and the arc input box 196 serve also to modify any existing segments. Updating a segment value simply requires typing in the new value for any of the fields.

The scale box 208 of the creation window 192 provides an option of specifying the line or arc parameters in either metric or U.S. standard units of millimeters or inches, respectively. The scale box 208 also includes image scale buttons for enlarging, shrinking or fitting the profile of the current profile view window 250, as shown in FIG. 13. A base option box 226, provides a selection for whether the current segment is the tip base, as shown in FIG. 5, which will include a relief angle λ in order to avoid heeling, as is known in the art.

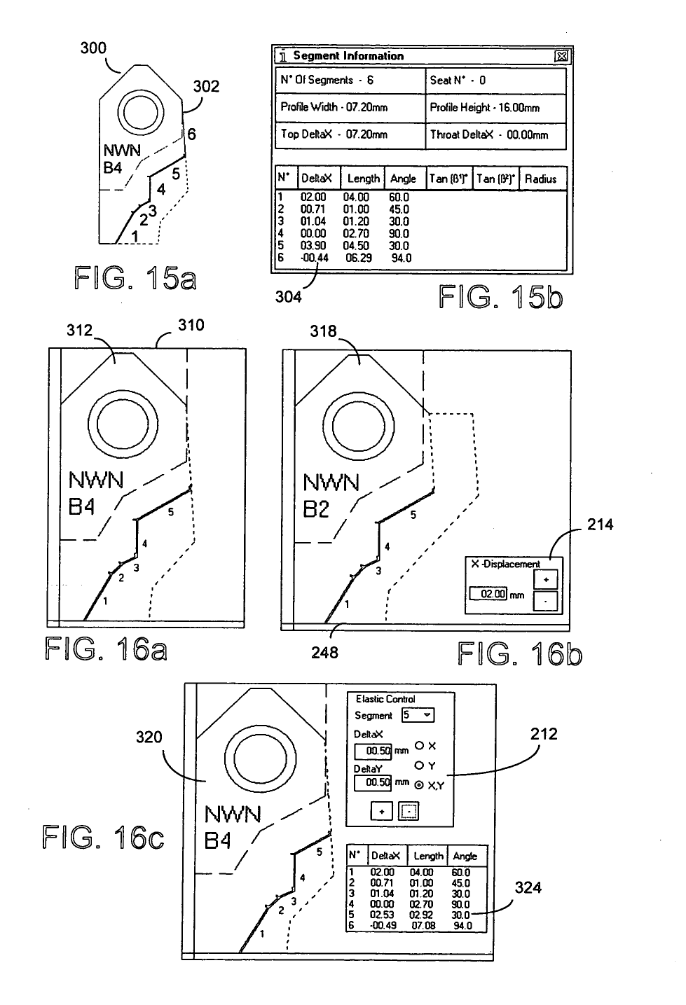

The elastics window 206, shown in FIG. 11, provides flexibility in the modification of an existing profile. The elastic control box 212 provides controls for increasing or decreasing a radius or length along the x-axis and/or the y-axis. Each selection of the “+” or “−” button increments or decrements the “DeltaX” and/or the “DeltaY” by the entered values. In a preferred embodiment, the DeltaX operation is carried out prior to the DeltaY if both are supplied with an increment value. FIG. 16c illustrates the use of the elastics control box of FIG. 11. An original profile is shown in a work area window 310 in FIG. 16a, with the segment information illustrate in FIG. 9. Referring back to FIG. 16c, the elastic control box 212 is updated to select segment 5. A DeltaX and a DeltaY are specified as 0.5 mm with the option to modify the chosen segment along both the x-axis and the y-axis. In the example of FIG. 16c, the chosen segment is decreased in length utilizing the “−” button. A comparison between the modified tip 320 of FIG. 16c and the original tip 312 of FIG. 16a reveals that the fifth segment is modified by the specified values. The segment information box 324, shown in FIG. 16c, also verifies the reduction in the DeltaX and the length of fifth segment.

Referring again to FIG. 11, a passive segment box 216 provides an “Auto” button for adding a new passive segment to the profile. This new passive segmentwill automatically extend to the maximum permitted height of the Blank. In addition, the passive segment will automatically re-adjust its height when any of the other profile segments are changed. The inclusion of a passive segment in the profile specification allows the total profile height to remain constant. The profile of a preferred embodiment contains only one passive segment, which may be used in conjunction with an Active Elastic Segment. FIGS. 15a and 15b illustrate the addition of an passive segment 302 having segment specifications 304 that follow the edge of the blank tip 300. The passive segment values change when a profile segment is modified utilizing the elastic controls 212, as shown in the segment information box 324 of FIG. 16c.

Continuing with FIG. 11, an X-Displacement box 214 of the elastics window 206 provides a control for moving an entire profile along the x-axis by the user-specified value. The “+” and “−” buttons may be used to move the profile to the left or to the right. The entire profile is movable along the x-axis provided that the profile height matches exactly the height of the tip. To aid in the management of the profile height, the “Auto” button of the passive segment box 216 may be selected. Selection of this button will automatically add a segment to the profile, then adjust the segment to the difference between the current profile height and the tip height. FIGS. 16a and 16b illustrate an x-displacement. A value of 2 mm is entered in the X-Displacement box 214, and a single selection of the “+” button moves the entire profile along the x-axis 248. A passive segment is included in this example which allows the profile to be moved outside of the boundaries of a first blank tip 312. In response, the bit-design program automatically chooses and overlays a larger blank bit 318. The elastics window further includes segment information 218 and profile information 220.

FIG. 12 illustrates a blanks window 204 of the toolbox 190 of a preferred embodiment. Other embodiments may include more or less blank tips depending upon a manufacturer's blank tip inventory. A blank tip may be chosen by clicking on its image. Ideally, a blank tip is chosen according to a closest fit with the custom profile design. The relief angle can either be chosen from the preset values or entered directly the other.

FIG. 17 illustrates a method of doing business 400 between a bit manufacturer 420 and a customer 414, 416 requiring the manufacture of a custom bit. A bit-design program is provided to a customer 414, 416 via a hard copy 418, e.g., a disk containing a copy of the program, or via electronic access, e.g., the Internet or e-mail. The bit-design software is utilized by a customer on the customer's personal computer 414, 416. The customer designs a custom cutting bit and delivers the completed design to the bit manufacturer 420. The design may be printed to provide a hard copy 418 to the bit manufacturer 420. In a preferred embodiment of the present invention, the finished design is uploaded to a central computer 406 located at the bit manufacturer 420. In a preferred embodiment, compatibility between the design program software and the software of the bit profile/cutting machine 408 allows the finished profile design specifications to be entered into the bit profile/cutting machine 408 directly through a connection to the central computer. In another embodiment, the design specifications are entered manually by a cutting machine operator. The bit design software stores data that is pertinent to a particular engine type, and thus, the software is usable as a management tool to simplify the work of the machine operator, including specifying which carbide tip profile may be utilized for a given cylinder head model. The method of doing business as illustrated in FIG. 17 reduces the time and cost to design and manufacture a custom cutting bit.

Obviously, other embodiments and modifications of the bit-design program and method of designing a custom bit of the present invention will occur readily to those of ordinary skill in the art in view of these teachings. Therefore, this invention is to be limited only by the following claims, which include all such other embodiments and modifications when viewed in conjunction with the above specification and accompanying drawings.

We claim:

1. A system for designing custom cutting bit profiles for use in machining a cylinder engine head, the system comprising:
a bit-design software program having means for creating, modifying, and storing specifications of the custom cutting bit profiles;
a customer computer for executing the bit-design software program;
a bit manufacturer computer; and
a transfer medium for transferring the specifications from the customer computer to the bit manufacturer computer.

2. The system of claim 1, wherein the transfer medium is a removable memory device.

3. The system of claim 1, wherein the transfer medium is electronic mail.

4. The system of claim 1, wherein the transfer medium is an Internet connection.

5. A software design program for creating a diagram and specifications for a cutting tip profile for use in manufacturing a custom cutting tip utilized in a machining apparatus for machining a valve seat of a cylinder engine head, the software design program comprising:
an active work area for displaying the diagram;
a tool box window for creating and modifying the cutting tip profile of the diagram, the tool box window further comprising:
a creation window having means for specifying a plurality of segments, the plurality of segments forming the cutting tip profile;
an elastics window having means for modifying an elastic segment of the plurality of segments; and
a blank tips window for displaying a plurality of available blank template bits;
wherein the software design program automatically overlays the cutting tip profile on a selected blank template bit of the plurality of available blank template bits.

6. The software design program of claim 5, wherein the segment is a line segment defined by an angle and one of a length and a change along an axis.

7. The software design program of claim 5, wherein the segment is an arc segment defined by a start tangent, a stop tangent and a radius.

8. The software design program of claim 5, further comprising a calculator for determining the positioning of a tip holder of the machining apparatus from a plurality of position values, the tip holder for holding the custom cutting tip.

9. The software design program of claim 8, wherein the plurality of position values comprises a valve diameter value, a pilot diameter value, and a margin value.

10. The software design program of claim 5, wherein the elastics window further comprises a passive segment option for adding a passive segment to the profile, the passive segment for automatically extending the cutting tip profile to a maximum permitted height of the selected blank template bit.

11. The software design program of claim 5, further comprising a print option for printing the diagram.

12. The software design program of claim 11, wherein the diagram is printed in a blue-print format.

13. A method of designing a custom bit for machining a valve seat of a cylinder engine head, the method comprising the steps of:
selecting a template tip from a plurality of template tips;
specifying a plurality of segments;
overlaying the plurality of segments on the template tip to create a representation of the custom bit; and
sending the representation to a bit manufacturer.

14. The method of claim 13, wherein the step of selecting a template tip comprises the step of selecting a profile from a database of profiles, each profile of the database of profiles having a predetermined plurality of segments, and wherein the step of specifying a plurality of segments comprises the step of modifying the predetermined plurality of segments.

15. A tip holder adjustment calculator for calculating a positioning of a tip holder on a tool holder of a machining apparatus for machining valve seats of a cylinder engine head, the tip holder adjustment calculator utilizing values derived from the valve seats and a valve for placement in the valve seat, the calculator comprising:
a first entry point for entering a valve diameter of the valve;
a second entry point for entering a pilot diameter of the valve; and
a third entry point for entering a margin between a valve seat contact and the valve seat; and
a tip measurement area for displaying the positioning of the tip holder;
wherein the positioning is calculated from the valve diameter, the pilot diameter, and the margin, and wherein the positioning defines a distance between a machining head pilot and the tip holder.

16. A method of doing business between a tip manufacturer and a customer for creating a custom tip for use in machining engine cylinder heads, the method comprising the steps of:
supplying an automated tip profile design program to the customer;
creating a custom tip utilizing the automated tip profile design program, wherein the customer performs a design procedure to create the custom tip, the design procedure comprising the steps of:
selecting a blank profile;
specifying at least one profile segment; and
saving the custom tip in a tip file; and
delivering the tip file to the tip manufacturer.

17. The method of doing business of claim 16, wherein the step of delivering the tip file comprises the step of uploading the tip file to the tip manufacturer utilizing an electronic means.

18. The method of doing business of claim 16, wherein the step of supplying an automated tip profile design program comprises the step of downloading the automated tip profile design program to the customer utilizing an electronic means.
